(19) United States
(12) Patent Application Publication
(10) Pub. No.: US 2008/0123287 A1
(43) Pub. Date: May 29, 2008

(54) Casings for hand-held electronic devices

(75) Inventors: William John Charles Rossell, London (GB); Jonathan Lam, Kowloon (HK)

Correspondence Address: Breiner & Breiner, L.L.C., P.O. Box 320160, Alexandria, VA, 22320-0160, US

(73) Assignee: Addonit Limited, London (GB)

(21) Appl. No.: 11/984,928

(22) Filed: Nov. 26, 2007

(30) Foreign Application Priority Data
Nov. 27, 2006 (GB) 0623629.3

(51) Int. Cl. H05K 7/00

(52) U.S. Cl. 361/686; 361/679

(57) ABSTRACT

Two-part casings are described which have the dual function of enclosing and protecting a hand-held electronic device, for example a music player in one portion of the casing and an accessory to the device such as a battery pack or loudspeaker system. The overall assembled casing is still a hand-held portable unit. A connector (5) inside one portion of the casing may be electrically connected to a connector (6), for example a mini USB socket, for mating with a mini USB plug on the second casing portion which has the accessory located in it.

This invention relates to-casings for hand-held electronic devices.

In recent years, a wide variety of hand-held electronic devices has been developed. These take advantage of the considerable developments in microelectronics and circuit fabrication and enable users of such devices to carry them easily.

Examples of such devices are mobile telephone handsets, personal digital assistants, various types of music player and digital cameras.

Such devices are usually sold accompanied by casings for protecting them for example to reduce the risk of damage from abrasion, entry of dust or grit, and to cushion against shock if the device is dropped. For greater protection, more effective casings may be purchased, for example waterproof casings. US-A-2005/0174727 discloses waterproof casings for PDAs and discloses the use of a connector in the casing designed to mate with the connector on the PDA, so enabling it, without being extracted from the protective casing, to interact with other devices.

Other protective casings for PDAs are disclosed in US-A-2002/0163778, U.S. Pat. No. 020,858 and U.S. Pat. No. 6,317,313. The disclosures of the latter two specifications include the casing having a portion into which an external device may be inserted, for example a memory card or an audio transducer, that part being connected to a connection member in the port of the casing which receives the PDA.

The systems described in the prior art are inflexible and do not easily permit the convenient interchangeable use of different accessories with the same hand-held electronic device without the provision of a separate casing for the accessory.

In accordance with the present invention, there are provided two part protective casings where one part serves as an interface between the device itself and an electric or electronically active hand-held accessory, and the other part embodies the accessory itself.

Accordingly, the present invention provides a casing for a hand-held electronic device, the casing comprising a first portion configured to fit closely around part of the exterior of the device, and to provide protection to the device, and wherein the first portion of the casing is fitted with first means adapted, when the device is inserted into the first portion of the casing, to contact electrical terminals forming part of the device and with second means electrically connected to the first means and adapted to contact electrical terminals forming part of an accessory for the hand-held electronic device, and characterised in that the casing comprises a second portion detachable from the first portion, incorporating an accessory, and configured, when assembled to the first portion, to form a complete protective casing surrounding the device.

The casing portions may be made of a wide variety of materials. Preferred are rubbery plastics materials, for example silicone materials. These may easily be moulded to a shape which fits closely around part of the device and the contact means, usually a plug, a socket and wiring between them, may be moulded into the first casing part without difficulty. Likewise, they may be moulded around a variety of accessories, and in such a way as to leave exposed connection means enabling connection to be established between the device and the accessory when the casing portions are assembled together. Other materials may, however, be used to form, or form part of, the casing portions, for example textile materials, leather and leather substitutes. The casing may have a laminated structure, for example an inner shell surrounded by an outer resilient skin. In any case, contact means in the first portion need to be held firmly in position so that they engage operatively with the device when it is inserted into the first portion of the casing.

Forming the first portion of the casing of resilient material enables the first portion of the casing to be fitted round the hand-held electronic device simply and securely and enables it to be designed avoiding fitments such as catches or hinges which can suffer failure in subsequent use.

The second casing portion is complementary to the first so that, when assembled, they form a complete casing around the device. In a further development, the first portion of the casing essentially replicates the outside of the hand-held electronic device, i.e. the outside of the first portion of the casing bears plug/socket arrangements which are essentially identical to those on the device, while the interior of the casing has socket/plug arrangements which mate with the plug/socket arrangements on the exterior of the hand-held electronic device when it is inserted into the first portion of the casing. The first portion of the casing has electrical terminal connection means, which may differ from those on the outside of the device, but which are engaged by a plurality of available accessories in a range of second casing portions.

The first and second casing portions preferably have mutually inter-engaging means which act to guide the second portion on to the first to enable connection of the accessory in the second casing portion to the device. The two casing portions, the device and the accessory all form a coherent handheld unit.

The second portions of the casings in accordance with the present invention may embody a wide variety of accessories. Examples include:
means for the supply of power to, or to recharge an internal power source in, the electronic device. Such power may be provided, for example, by a battery pack accessory which may in turn include a solar panel to provide an additional source of power. If the hand-held electronic device does not require very much power, then the accessory may even be configured as a pure solar panel and its associated electronics, i.e. the accessory need not include any power storage.
means providing signal output from the hand-held electronic device.

If the hand-held electronic device is, for example, some form of stored music player, then the accessory may, for example, be a loudspeaker unit so that music can be listened to without the aid of headphones.
means enabling signal input to the hand-held electronic device. If the device is a music player, the accessory may be an electronic device arranged to download a music track from the internet and then feed it into the music player located in the first portion of the casing.
a very low power short-range FM transmitter which may be used in conjunction with a music storage device to transmit music stored in the device to FM wireless receivers located nearby.

A particularly useful form of plug and socket connection for use between the two portions of the casing is a mini USB plug and socket connection. Preferably the accessories for use in conjunction with the hand-held electronic device are provided with a mini USB plug for mating with a mini USB socket in the first casing portion.

The invention can be applied to the provision of casings for hand-held electronic devices and coordinated sets of accessories for a very wide variety of hand-held electronic devices, including mobile telephone handsets, PDAs, MP3 and MP4 music players, high capacity digital storage music players as commercialised under the trade marks iPOD and ZUNE, digital cameras, GPS navigational apparatus and hand-held computers.

As noted above, the exterior of the first casing portion may have connection means replicating those on the hand-held device. This enables the device, even when in a casing according to the invention, to be inserted into a known docking unit or like base device, or to be inserted into a larger accessory unit, for example a powered loudspeaker base station when the device is a music player, enabling a much greater power audio output to be achieved but without having to extract the music player from the first portion of the casing and plug it into the loudspeaker base station itself.

By way of example, one embodiment of the present invention is illustrated in the accompanying drawings. In the particular example chosen, the hand-held electronic device is a standard Apple iPOD (registered trade mark) music player.

In the drawings:

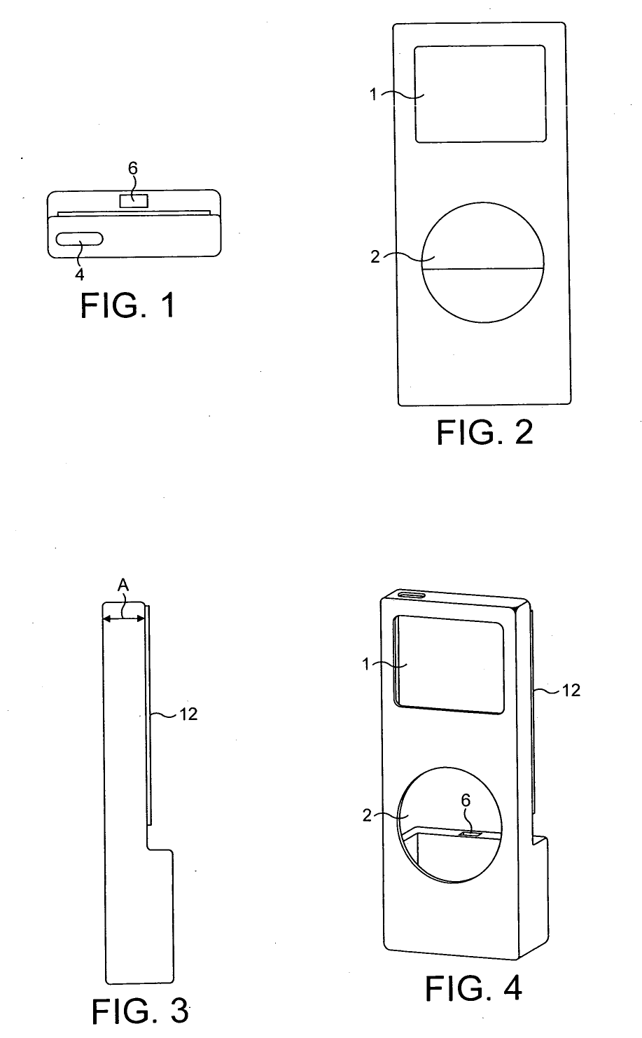

FIGS. 1 to 4 are respectively outline top, front, side and perspective views of the first portion of a casing in accordance with the present invention;

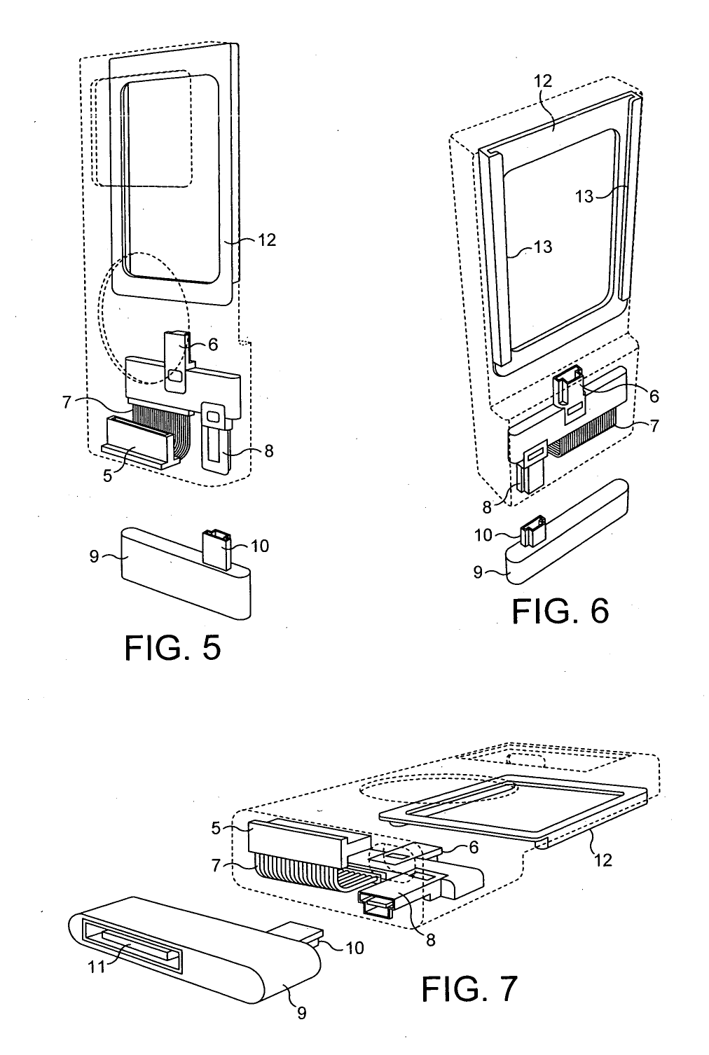

FIGS. 5, 6 and 7 are each perspective diagrammatic views of the casing portion shown in FIGS. 1 to 4 showing the internal arrangements, together with an inter-connector module;

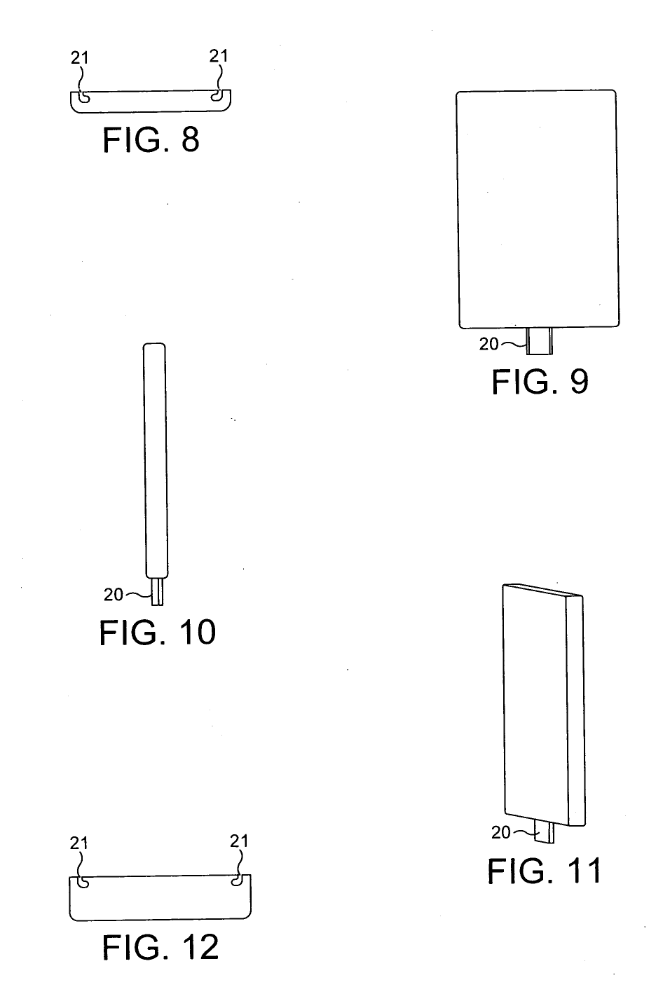

FIGS. 8 to 11 are respectively top, front, side and perspective views of a battery accessory in a second casing portion;

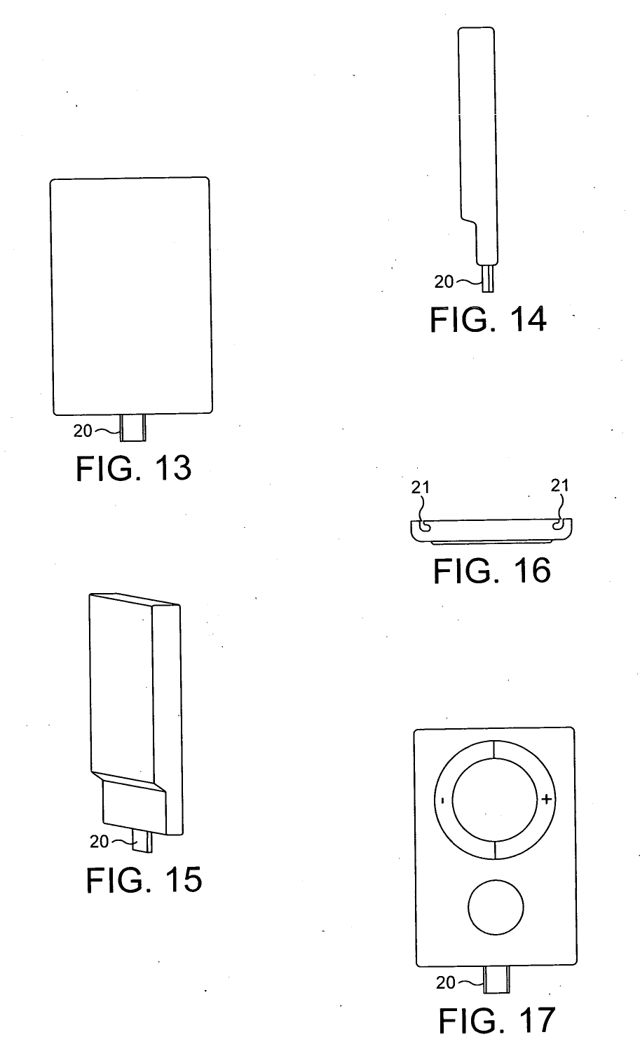

FIGS. 12 to 15 are figures similar to FIGS. 8 to 1 1, but showing a high capacity battery accessory in a second casing portion;

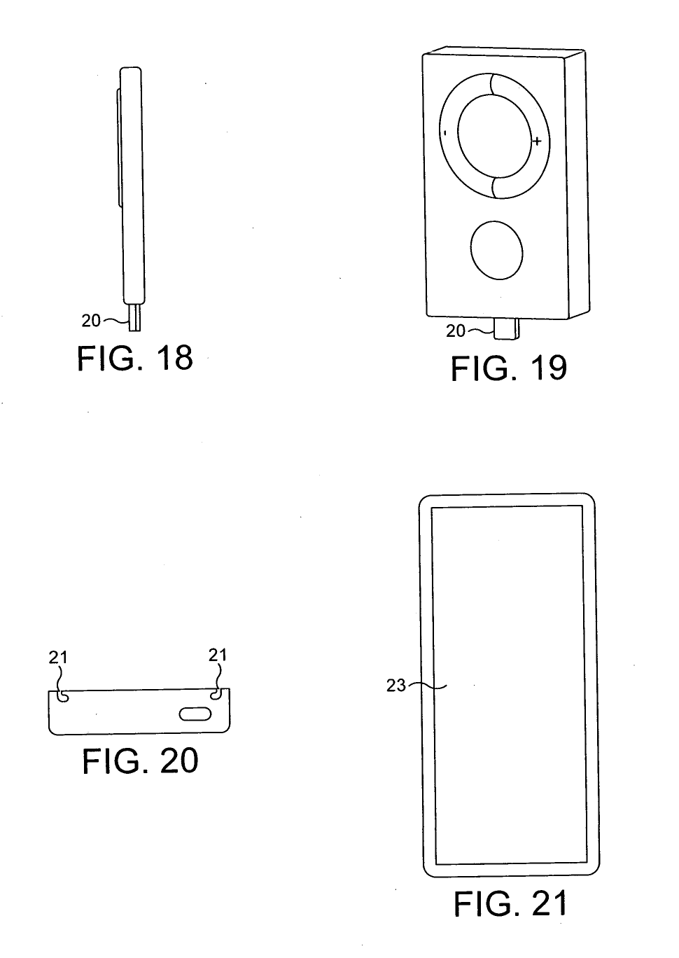

FIGS. 16 to 19 are corresponding figures showing a casing portion incorporating an FM transmitter unit accessory, for assembly with a casing as shown in FIGS. 1 to 7;

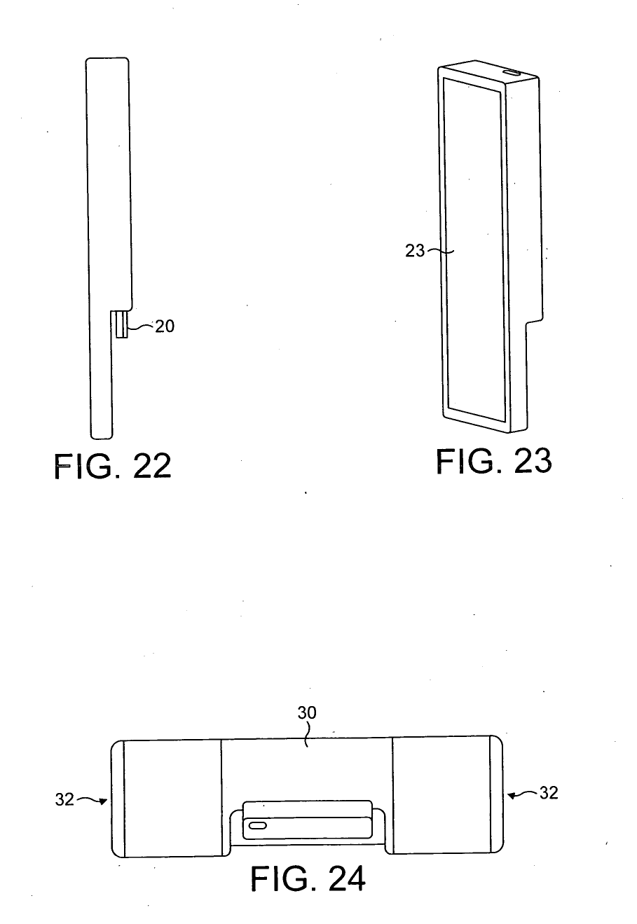

FIGS. 20 to 23 show a corresponding casing portion incorporating a solar panel accessory; and

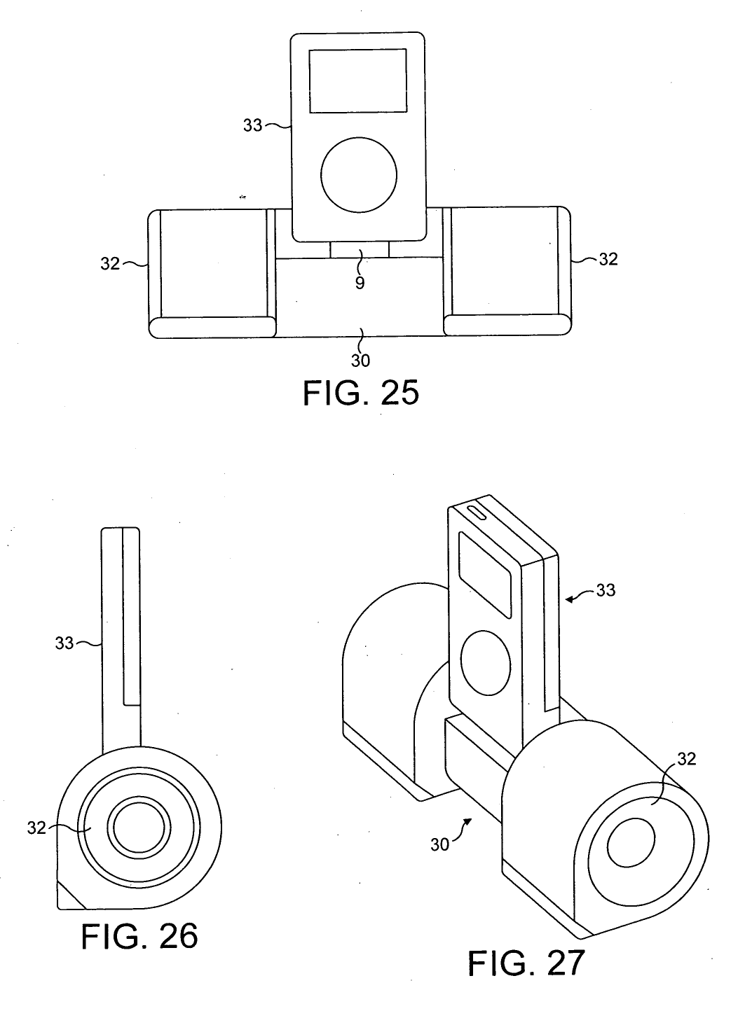

FIGS. 24 to 27 are diagrammatic views of a casing according to the present invention inserted into an accessory consisting of a loudspeaker and battery pack unit.

Referring first to FIGS. 1 to 7, these show a moulded silicone rubber casing portion for a music player device. It consists basically of a moulding which is designed to fit closely around part of the music player device and which has two windows formed in it, an upper window 1 through which the display screen of the music player device may be seen and a lower window 2 through which the controls for the music player device may be accessed.

The casing portion is dimensioned so that the player device itself fits into the casing portion exactly, i.e. its depth is as indicated by double-headed arrow A on FIG. 3.

The top of the casing portion includes an elongate aperture 4 which will register with the hold switch of the music player device. Located in the base of the casing portion and shown only in FIGS. 5 to 7 of the drawings is a connector 5 which is adapted, when the music player is inserted into the casing portion to contact the terminal means on the bottom of the music player. Set in a rear part of the casing portion is a mini USB socket 6. By means of appropriate connector wires 7 moulded into the casing, USB socket 6 is connected to connector 5 which in turn connects to the music player device when it is inserted into the casing.

Also connected to connector 5 and socket 6 is a further USB socket 8 accessible from the bottom of the casing. An interconnecting module 9 with a USB plug 10 may be inserted into socket 8, and present, on its side opposed to plug 10, a socket 11 (only visible in FIG. 7) which matches the socket on the bottom of the player.

The rear of the casing portion carries a frame 12 having opposed rails 13.

FIGS. 8 to 23 show second casing portions incorporating various accessories which may be used in conjunction with the music player set in the casing portion shown in FIGS. 1 to 7. Each has a mini USB plug connector 20 which is plugged into socket 6 when the two casing portions are assembled together. Each second casing portion has a pair of opposed slots 21 into which rails 13 fit, so that when the first and second casing portions are assembled together connector 20 moves smoothly into socket 6.

As shown in FIGS. 8 to 11, the accessory in the second casing portion is a slimline battery pack. It consists of rechargeable batteries and is configured so that it automatically recharges the music player device when connected. It may itself be recharged using appropriate equipment as and when needed. Indeed, it may be arranged that the slimline battery pack itself has a socket enabling it to be recharged when the music player itself is connected to an external power source.

When the two casing portions are assembled, the overall configuration remains that of a compact unit not very much bigger than the original music player device.

FIGS. 12 to 15 are analogous to FIGS. 8 to 11, but illustrating a higher capacity battery pack which, as can clearly be seen from FIGS. 14 and 15, is bigger, i.e. of greater depth.

FIGS. 16 to 19 show the use of an FM transmitter unit as the accessory in the second casing portion. When the casing portions are assembled together and the music is used, the FM transmitter unit broadcasts a very low power FM signal so that a nearby FM radio can pick it up. This can be useful, for example, if a user wishes to play music stored in the music storage device in the casing via their car radio. No special wiring is required.

FIGS. 20 to 23 show second casing portions incorporating a solar panel accessory, a solar panel 23 extending over one face of the casing portion. The solar panel accessory unit includes an integrated battery which is continuously and automatically charged when light is falling on panel 23 and whether or not the casing portions are assembled together. When such assembly occurs, the solar panel unit may be arranged automatically to recharge any rechargeable battery in the music player. At the same time, if the solar panel 23 is still exposed to light, it continues to convert that light into energy and store that energy.

FIGS. 24 to 27 are views of a higher powered speaker unit. A battery powered unit 30 has a connector adapted to mate with the connector on the music player or the corresponding connector on the exterior of the casing. At either end of unit 30 is a loudspeaker 32. When the casing (denoted 33) containing the music player is plugged on to the device shown in FIGS. 24 to 27, the combined unit so formed may be used to produce an audible rendering of music stored in the music player via the loudspeakers 32. If desired (this is not shown in the Figures), the unit 30 may include controls enabling the volume and tone of the output to be modified by the user as desired.

1. A casing for a hand-held electronic device, the casing comprising a first portion configured to fit closely around part of an exterior of a hand-held electronic device, and to provide protection to the device, wherein the first portion of the casing is fitted with first means adapted, when the device is inserted into the first portion of the casing, to contact electrical terminals forming part of the device and with second means electrically connected to the first means and adapted to contact electrical terminals forming part of an accessory for the hand-held electronic device, and that wherein the casing further comprises a second portion detachable from the first portion, incorporating an accessory and configured, when assembled to the first portion, to form a complete protective casing surrounding the device.

2. A casing according to claim 1, wherein the first portion and the second portion are made of a rubbery plastics material.

3. A casing according to claim 2, wherein the first portion includes contact means and connector wiring therebetween, each being molded into the first portion.

4. A casing according to claim 1, 2 or 3, further comprising a first guide means on the first portion configured to engage a second guide means on the second portion including an accessory, to guide the first portion and the second portion upon assembly thereof to provide a plug/socket connection between the device and the accessory.

5. A casing according to claim 4, wherein the plug/socket connection includes a mini USB plug/socket connector.

6. A casing according to claim 1, wherein the accessory in the second portion of the casing is adapted to supply power to, or to recharge an internal power source in, the electronic device.

7. A casing according to claim 1, wherein the accessory in the second portion of the casing is capable of providing signal output from, or enabling signal input to, the hand-held electronic device.

8. An assembly comprising a casing according to claim 1, 2 or 3, and the hand-held electronic device located therein.

9. An assembly according to claim 8, wherein the hand-held electronic device is a mobile telephone handset, a PDA, a MP3 or MP4 player, a digital camera, a high capacity digital storage music player, a GPS navigational device or a hand-held computer.

10. An assembly according to claim 8, wherein the accessory in the second portion of the casing is a power supply unit, an audio reproduction unit designed to produce an amplified audio output, or a low power short-range FM transmitter.

11. An assembly according to claim 9, wherein the accessory in the second portion of the casing is a power supply unit, an audio reproduction unit designed to produce an amplified audio output, or a low power short-range FM transmitter.
